(19) United States
(12) Patent Application Publication
(10) Pub. No.: US 2010/0255286 A1
(43) Pub. Date: Oct. 7, 2010

(54) METHOD FOR MANUFACTURING RESIN SUBSTRATE

(75) Inventors: Keisaku MATSUMOTO, Yasu (JP); Katsura Hayashi, Yasu (JP)

Correspondence Address: Hogan Lovells US LLP, 1999 AVENUE OF THE STARS, SUITE 1400, LOS ANGELES, CA, 90067, US

(73) Assignee: Kyocera Corporation, Kyoto (JP)

(21) Appl. No.: 12/748,157

(22) Filed: Mar. 26, 2010

(30) Foreign Application Priority Data
Mar. 27, 2009 (JP) 2009-079903

(51) Int. Cl. B32B 5/24; B32B 37/06; H05K 3/00; C08L 33/24; H05K 3/30

(52) U.S. Cl. 428/315.5; 156/308.2; 427/96.1; 524/606; 428/317.9; 29/832

(57) ABSTRACT

A method for manufacturing a resin substrate includes heating a resin sheet including fibers and a resin containing incompletely polymerized molecules to a temperature lower than a polymerization initiation temperature of the resin in order to soften the resin; applying a first pressure to the resin sheet to discharge air bubbles between the fibers outside the resin sheet; decreasing the pressure applied to the resin sheet from the first pressure to a second pressure lower than the first pressure; and heating the resin sheet to the polymerization initiation temperature of the resin or higher to polymerize the molecules of the resin and to discharge a gas generated by the polymerization outside the resin sheet.

### BACKGROUND OF THE INVENTION

1. Field of the Invention

The present invention relates to a method for manufacturing a resin substrate included in a circuit substrate. Such a circuit substrate is used in electronic devices (for example, various audiovisual devices, household electrical appliances, communication devices, and computer devices and peripheral devices thereof) and the like.

2. Description of the Related Art

Heretofore, mounting structures have been produced by mounting an electronic component such as a semiconductor device or a capacitor on a circuit substrate. It is known that such a circuit substrate includes a resin substrate in order to increase the mechanical strength thereof.

Regarding a method for manufacturing a resin substrate, Japanese Unexamined Patent Application Publication No. 2403-340962 describes a method including a step of applying a resin, a step of heat-treating the resin, and a step of hot-pressing the resin.

Meanwhile, in order to increase the strength of the resin substrate, fibers may be impregnated with a resin in the step of applying the resin. In this case, air bubbles are formed between fibers during the impregnation, and the air bubbles tend to remain in the resin substrate. When such air bubbles remain in the resin substrate and a stress is added to the resulting circuit substrate, cracks are readily generated from the air bubbles as starting points. Consequently, the reliability of the circuit substrate tends to decrease.

### BRIEF SUMMARY OF THE INVENTION

The present invention provides a method for manufacturing a resin substrate that meets a requirement for improving the reliability of a circuit substrate.

A method for manufacturing a resin substrate according to an embodiment of the present invention includes heating a resin sheet including fibers and a resin containing incompletely polymerized molecules to a temperature lower than a polymerization initiation temperature of the resin in order to soften the resin; applying a first pressure to the resin sheet in order to discharge air bubbles between the fibers outside the resin sheet; decreasing the pressure applied to the resin sheet from the first pressure to a second pressure lower than the first pressure; and heating the resin sheet to the polymerization initiation temperature of the resin or higher in order to polymerize the molecules of the resin and to discharge a gas generated by the polymerization outside the resin sheet.

According to the method for manufacturing the resin substrate according to the embodiment of the present invention, air bubbles remaining in the resin substrate can be reduced. As a result, a circuit substrate and a mounting structure that have good reliability can be obtained.

### BRIEF DESCRIPTION OF THE DRAWINGS

FIG. 1 is a cross-sectional view of a mounting structure according to an embodiment of the present invention.

FIGS. 2A, 2B, and 2C are cross-sectional views illustrating steps of manufacturing the mounting structure shown in FIG. 1.

FIGS. 3A, 3B, and 3C are cross-sectional views illustrating steps of manufacturing the mounting structure shown in FIG. 1.

FIGS. 4A, 4B, and 4C are cross-sectional views illustrating steps of manufacturing the mounting structure shown in FIG. 1.

FIGS. 5A, 5B, and 5C are cross-sectional views illustrating steps of manufacturing the mounting structure shown in FIG. 1.

FIGS. 6A and 6B are cross-sectional views illustrating steps of manufacturing the mounting structure shown in FIG. 1.

### REFERENCE NUMERALS

1 mounting structure
2 electronic component
3 circuit substrate
4 bump
5 resin substrate
6 circuit layer
7 insulating base
7x laminate
8 through-hole conductor
9 insulator
10 resin layer
10x resin sheet
11 resin portion
11x incompletely polymerized resin portion
12 base material
13 insulating layer
13a first insulating layer
13b second insulating layer
14 conductive layer
14x copper foil
15 via-conductor
16 pressing member
T through-hole
V via-hole

### DETAILED DESCRIPTION OF EXEMPLARY EMBODIMENTS

A method for manufacturing a resin substrate according to an embodiment of the present invention is now described in detail with reference to the drawings using, as an example, a method for manufacturing a mounting structure, the method employing the method for manufacturing the resin substrate.

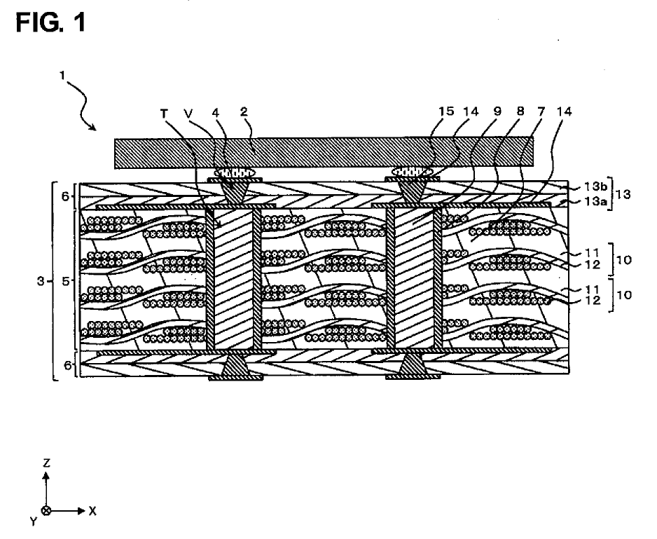

A mounting structure 1 shown in FIG. 1 is prepared by using a method for manufacturing a mounting structure according to this embodiment.

The mounting structure 1 is used in electronic devices such as various audiovisual devices, household electrical appliances, communication devices, and computer devices and peripheral devices thereof. This mounting structure 1 includes an electronic component 2 and a circuit substrate 3.

The electronic component 2 is a semiconductor device, for example, an IC, an LSI, or the like and is flip-chip mounted on the circuit substrate 3 through electrically conductive bumps 4 such as solder. The parent material of this electronic component 2 is composed of a semiconductor material, for example, silicon, germanium, gallium arsenide, gallium-arsenic-phosphorus, gallium nitride, silicon carbide, or the like. As the electronic component 2, a component having a thickness of, for example, 0.1 mm or more and 1 mm or less can be used.

The circuit substrate 3 includes a resin substrate 5 and a pair of circuit layers 6 formed on both surfaces of the resin substrate 5.

The resin substrate 5 increases the strength of the circuit substrate 3 and has a thickness dimension of, for example, 0.3 mm or more and 1.5 mm or less. This resin substrate 5 includes an insulating base 7, through-holes T, through-hole conductors 8, and insulators 9.

The insulating base 7 constitutes a main part of the resin substrate 5. This insulating base 7 is prepared by stacking a plurality of resin layers 10. Each of the resin layers 10 includes a resin portion 11 and a base material 12 covered with the resin portion 11.

The resin portion 11 constitutes a main part of the resin layer 10 and can be formed of, for example, a polyimide resin, an aromatic liquid crystal polyester resin, a polyether ether ketone resin, a polyether ketone resin, or the like. Among these, a polyimide resin is preferably used. Polyimide resins have a low coefficient of thermal expansion of 0 ppm/° C. or more and 15 ppm/° C. or less, and thus, the use of such a low-thermal expansion resin can suppress thermal expansion of the resin substrate 5 itself. Note that, as the polyimide resin, a thermosetting polyimide resin or a thermoplastic polyimide resin may be used. In addition, the coefficient of thermal expansion is in accordance with ISO11359-2:1999.

The base material 12 increases the strength of the resin layer 10. As the base material 12, a woven fabric in which a plurality of fibers, for example, glass fibers, resin fibers, carbon fibers, or the like are woven in the lengthwise and widthwise directions can be used. As the glass fibers, fibers formed of E-glass, S-glass, or the like can be used. As the resin fibers, fibers formed of a poly(p-phenylene benzbisoxazole) resin, a wholly aromatic polyamide resin, a wholly aromatic polyester resin, or the like can be used. As the carbon fibers, PAN-based carbon fibers, pitch-based carbon fibers, or the like can be used.

Each of the through-holes T is a portion in which the corresponding through-hole conductor 8 is formed and penetrates the resin substrate 5 in the thickness direction (Z direction). Each of the through-holes T is formed so as to have a columnar shape having a diameter of, for example, 0.1 mm or more and 1 mm or less.

Each of the through-hole conductors 8 electrically connects the circuit layers 6 to each other, the circuit layers 6 being disposed on the upper surface and the lower surface of the resin substrate 5, and are formed along the inner surface of the corresponding through-hole T. These through-hole conductors 8 are composed of an electrically conductive material, for example, copper, silver, gold, aluminum, nickel, or chromium.

Each of the insulators 9 fills the remaining space surrounded by the corresponding through-hole conductor 8. According to this structure, via-conductors 15 described below can be formed directly on and under each of the insulators 9, thereby realizing the reduction in size of the circuit substrate 3. Examples of a resin material that can be used for the insulators 9 include polyimide resins, acrylic resins, epoxy resins, cyanate resins, fluorocarbon resins, silicone resins, polyphenylene ether resins, and bismaleimide-triazine resins.

The circuit layers 6 are formed on both surfaces of the resin substrate 5 and each include an insulating layer 13, conductive layers 14, via-holes V, and the via-conductors 15. The conductive layers 14 and the via-conductors 15 are electrically connected to each other to constitute a circuit portion. This circuit portion includes lines for supplying electric power or lines for signals.

The insulating layer 13 ensures insulation of portions other than the circuit portion in the circuit layer 6 and is formed so as to have a thickness of, for example, 1 μm or more and 15 μm or less. The insulating layer 13 includes, for example, a first insulating layer 13a and a second insulating layer 13b.

The first insulating layer 13a is disposed between the second insulating layer 13b and the resin substrate 5 and bonds the second insulating layer 13b to the resin substrate 5. As the first insulating layer 13a, a layer formed of a thermosetting resin, for example, a polyimide resin, an acrylic resin, an epoxy resin, a urethane resin, a cyanate resin, a silicone resin, a bismaleimide-triazine resin, or the like can be used. Note that the coefficient of thermal expansion of the first insulating layer 13a is set to be, for example, 16 ppm/° C. or more and 40 ppm/° C. or less.

The second insulating layer 13b is not provided with a base material and contains a low-thermal expansion resin, and thereby the difference in the coefficient of thermal expansion between the circuit substrate 2 and the electronic component 3 is decreased. As the second insulating layer 13b, a layer formed of a low-thermal expansion resin, for example, a liquid crystal polymer, a polybenzoxazole resin, a polyimide benzoxazole resin, or the like is preferably used. Note that the coefficient of thermal expansion of the second insulating layer 13b is set to be, for example, −10 ppm/° C. or more and 5 ppm/° C. or less.

The insulating layer 13 may contain a filler. As a material for forming the filler, a material having a coefficient of thermal expansion of −5 ppm/° C. or more and 5 ppm/° C. or less, for example, silicon oxide (silica), silicon carbide, aluminum oxide, aluminum nitride, or aluminum hydroxide can be used.

The conductive layers 14 constitute a circuit portion together with via-conductors 15 described below and are separated from each other in the thickness direction. These conductive layers 14 are composed of a metallic material, for example, copper, silver, gold, aluminum, nickel, chromium, or the like.

Each of the via-holes V is a portion in which the corresponding via-conductor 15 is formed and penetrates the insulating layer 13 in the thickness direction (Z direction). These via-holes V are formed so as to have, for example, a tapered shape narrowing toward the resin substrate 5 and are formed so that the cross section of each of the via-holes V in the plane direction (X-Y plane direction) has a circular shape having a diameter of, for example, 0.02 mm or more and 0.1 mm or less.

Each of the via-conductors 15 connects the conductive layers 14, which are arranged apart from each other with a space therebetween in the thickness direction, and is formed in the corresponding via-hole V. Each of the via-conductors 15 is formed so as to have a columnar shape and composed of an electrically conductive material, for example, copper, silver, gold, aluminum, nickel, or chromium.

Here, in the resin substrate 5 according to this embodiment, in a cross section cut in the thickness direction, the diameter of air bubbles contained between the fibers of the base material 12 is 0.1 μm or more and 3 μm or less. Consequently, since the diameter of air bubbles contained between the fibers of the base material 12 is small, cracks generated from the air bubbles as starting points can be reduced when a stress is added to the circuit substrate. Thus, a circuit substrate having good reliability can be obtained.

Note that air bubbles contained between the fibers of the base material 12 can be confirmed by observing a cross section of the resin substrate 5 with a scanning electron microscope, for example.

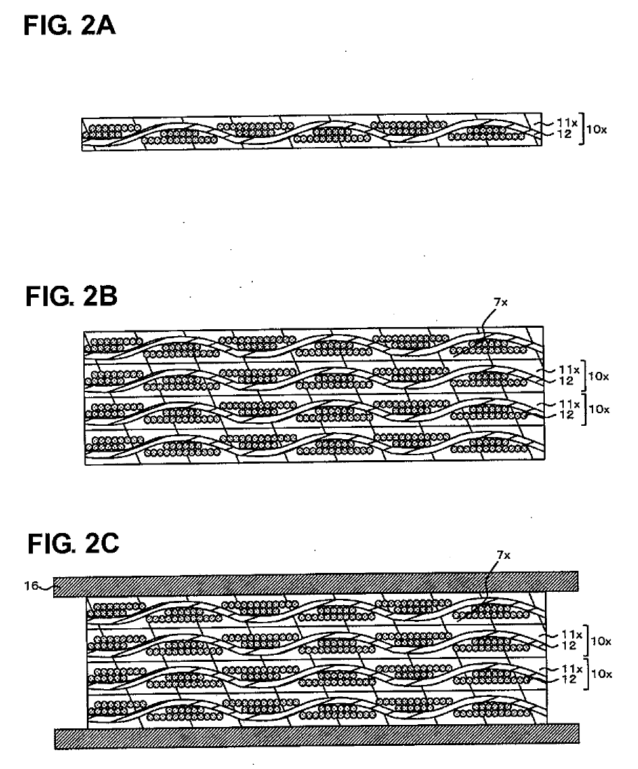

Next, a method for manufacturing the mounting structure 1 described above is described with reference to FIGS. 2 to 6.

(1) As shown in FIG. 2A, a resin sheet 10x is prepared by impregnating a base material 12 with an incompletely polymerized resin portion 11x.

The incompletely polymerized resin portion 11x is a resin in which an incompletely polymerized resin containing incompletely polymerized molecules is dissolved in a solvent.

A resin containing incompletely polymerized molecules and having a low degree of polymerization is used as the incompletely polymerized resin, and the incompletely polymerized resin becomes the above-described resin portion 11 with the progress of polymerization. Specifically, for example, when a thermosetting polyimide resin is used as the resin portion 11, a mixture of pyromellitic dianhydride or a carboxylic acid and aniline or a diamine can be used as the incompletely polymerized resin. Alternatively, when a thermoplastic polyimide resin is used as the resin portion 11, a mixture of a pyromellitic dianhydride and 4,4′-bis(3-aminophenoxy)biphenyl can be used as the incompletely polymerized resin. Note that the degree of polymerization is in accordance with ISO472:1999.

A solvent that dissolves the incompletely polymerized resin is used as the solvent. For example, dimethylacetamide or the like can be used.

A material the same as the base material 12 described above is used as the base material 12. Since the base material 12 includes a plurality of fibers, air bubbles may remain between fibers of the base material 12 when the base material 12 is impregnated with the incompletely polymerized resin portion 11x. For example, when the base material 12 is a woven fabric, air bubbles tend to remain at positions at which the fibers intersect each other. Such air bubbles can be confirmed by observing a cross section of the resin substrate 5 with a scanning electron microscope, for example.

When impregnating the base material with the incompletely polymerized resin portion 11x, if the viscosity of the incompletely polymerized resin portion 11x is high and set to be, for example, 2 mPa·s or more and 500 mPa·s or less, air bubbles tend to remain. The method for measuring the viscosity is in accordance with ISO3219:1993.

(2) As shown in FIG. 2B, a plurality of resin sheets 10x are stacked to form a laminate 7x.

(3) The laminate 7x is heated to a temperature lower than the polymerization initiation temperature of the incompletely polymerized resin to soften the incompletely polymerized resin. As a result, the viscosity of the incompletely polymerized resin portions 11x can be decreased. Note that the polymerization initiation temperature refers to a temperature at which the viscosity of a sample starts to increase when a change in the viscosity is measured by the above-mentioned method for measuring the viscosity while heating the sample.

(4) As shown in FIG. 2C, a first pressure is applied to the laminate 7x in which the incompletely polymerized resin is softened to discharge air bubbles between fibers of the base material 12 outside the laminate 7x.

Specifically, pressing members 16 are brought into contact with the upper surface and the lower surface of the laminate 7x while maintaining the temperature in step (3), and the first pressure is applied to the laminate 7x using the pressing members 16. Thus, since the viscosity of the incompletely polymerized resin portions 11x has been decreased and the flowability thereof has been increased, the incompletely polymerized resin portions 11x can be flowed to enter between fibers of the base material 12. As a result, by discharging the air bubbles remaining between fibers of the base material 12 in step (1) outside the laminate 7x, the air bubbles remaining in the laminate 7x can be decreased. In particular, air bubbles having a diameter larger than 3 μm can be efficiently discharged outside the laminate 7x. Accordingly, it is possible to form a resin substrate 5 in which the diameter of air bubbles contained between the fibers of the base material 12 is 0.1 μm or more and 3 μm or less in a cross section cut in the thickness direction.

In addition, since the first pressure is applied to the laminate 7x in a state in which the viscosity of the incompletely polymerized resin portions 11x is decreased, the adjacent resin sheets 10x can be brought into close contact with each other. As a result, in step (7) described below, the adhesive strength between resin layers 10 can be increased.

Note that the first pressure is preferably set to be 0.5 MPa or more and 10 MPa or less from the standpoint that the air bubbles are efficiently discharged outside the laminate 7x. In addition, from the same standpoint, the viscosity of the incompletely polymerized resin portions 11x in this step is preferably set to be, for example, 100 Pa·s or more and 5,000 Pa·s or less. In addition, from the same standpoint, the ambient pressure in this step is preferably set to be 0.2 atm or less. The air pressure can be measured with a diaphragm vacuum gauge, a Pirani vacuum gauge, or the like.

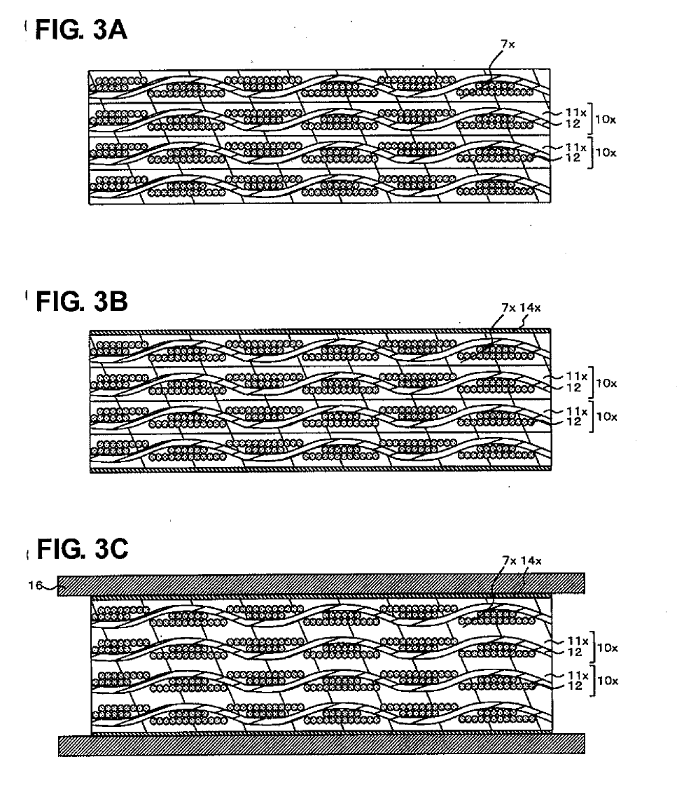

(5) As shown in FIG. 3A, the laminate 7x is heated to the polymerization initiation temperature of the incompletely polymerized resin or higher while applying a second pressure lower than the first pressure. Thus, by polymerizing molecules contained in the incompletely polymerized resin while applying the second pressure lower than the first pressure, a gas generated during a polymerization reaction can be efficiently discharged outside the laminate 7x. As a result, air bubbles generated in the laminate 7x by such, a gas can be decreased.

Note that the second pressure is preferably set to be 0.05 MPa or less from the standpoint that such a gas is discharged outside the laminate 7x. In particular, preferably, the pressure applied from the pressing members 16 is set to be zero, and the second pressure is set to be the air pressure in the atmosphere without bringing the pressing members 16 into contact with the laminate 7x. Thus, since the pressure applied to the laminate 7x is decreased and at least one main surface of the laminate 7x can be exposed, the gas can be efficiently discharged outside the laminate 7x.

In addition, the air pressure in this step may be atmospheric pressure, but is preferably set to be 0.8 atm or less from the standpoint that such a gas is discharged outside the laminate 7x. Furthermore, when a resin, the properties of which easily change, is used as the incomplete resin, the air pressure is preferably set to be 0.2 atm or less. Furthermore, this step may be conducted in an atmosphere of an inert gas such as argon gas.

In addition, in this step, it is desirable not to completely polymerize the incompletely polymerized resin. This is because a polymerization reaction is allowed to occur in the incompletely polymerized resin in step (7) described below. Furthermore, the viscosity of the incompletely polymerized resin portions 11x whose polymerization reaction has proceeded in this step is set to be 5,000 Pa·s or more and 50,000 Pa·s or less.

(6) As shown in FIG. 3B, copper foils 14x are stacked on both surfaces of the laminate 7x.

(7) As shown in FIG. 3C, the laminate 7x is heated to the polymerization initiation temperature of the incompletely polymerized resin or higher while applying a third pressure higher than the second pressure. Thus, by polymerizing molecules contained in the incompletely polymerized resin while applying the third pressure higher than the second pressure, the polymerization reaction between respective incompletely polymerized resins of the adjacent resin sheets 10x can efficiently proceed. As a result, the adhesive strength between the adjacent resin sheets 10x can be increased.

In addition, since the pressure is applied to the laminate 7x and the copper foils 14x while increasing the flowability of the incompletely polymerized resin portions 11x by the heating, the adhesive strength between the laminate 7x and each of the copper foils 14x can be increased.

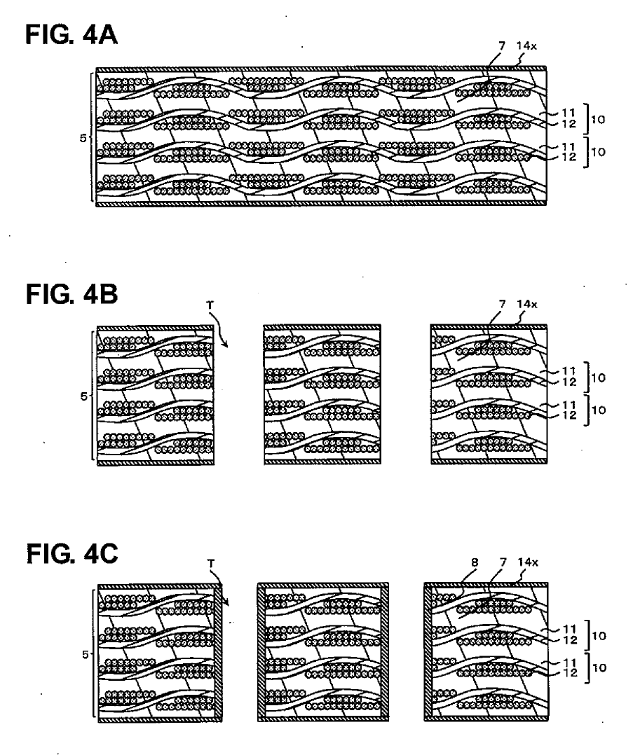

By developing the polymerization reaction of the incompletely polymerized resin in this manner, the resin sheets 10x become resin layers 10, and the laminate 7x becomes an insulating base 7. Thus, as shown in FIG. 4A, a resin substrate 5 including the insulating base 7 and the copper foils 14x can be prepared.

In this step, since the third pressure higher than the second pressure is applied to the laminate 7x in which the copper foils 14x are stacked on both surfaces thereof, a gas generated during the polymerization reaction is not readily discharged outside the laminate 7x. However, since such a gas generated during the polymerization reaction is discharged outside the laminate 7x in step (5), generation of a gas in this step can be reduced so as to reduce air bubbles generated in the laminate 7x.

In addition, the temperature in this step is preferably higher than the temperature in step (5). As a result, in step (5), by decreasing the polymerization rate, the gas can be discharged while reducing the possibility in which the gas generated during the polymerization reaction becomes voids. In this step, by increasing the polymerization rate, the adhesive strength between the adjacent resin sheets 10x can be efficiently increased.

Furthermore, from the standpoint of the adhesive strength between resin layers 10, the third pressure is preferably set to be 0.5 MPa or more and 10 MPa or less. In addition, the air pressure in this step is preferably set to be 0.2 atm or less from the standpoint that a gas generated during the polymerization reaction is discharged outside the laminate 7x. In addition, from the standpoint of the strength of the resin substrate 5, the viscosity of the incompletely polymerized resin portions 11x whose polymerization reaction has proceeded in this step is preferably set to be high to an extent that the viscosity cannot be measured by the above-mentioned method for measuring the viscosity.

(8) As shown in FIG. 4B, a plurality of through-holes T penetrating in the thickness direction are formed in the resin substrate 5. The through-holes T can be formed by, for example, drilling, laser machining, or the like. In addition, the width of the through-holes T is preferably set to be, for example, 0.1 mm or more and 1 mm or less.

Note that, by bringing the adjacent resin sheets 10x into close contact with each other in step (4), the adhesive strength between the resin layers 10 is increased in step (7). Accordingly, when the through-holes T are formed in this step, detachment between resin layers 10 exposed to the inner wall surfaces of the through-holes T can be reduced so as to reduce the space formed by such detachment.

(9) As shown in FIG. 4C, the inner wall surfaces of the through-holes T are coated with an electrically conductive material to form cylindrical through-hole conductors 8. The coating with such an electrically conductive material is performed by, for example, electroless plating, an evaporation method, a CVD method, a sputtering method, or the like.

Note that, by bringing the adjacent resin sheets 10x into close contact with each other in step (4), the space between resin layers 10 exposed to the inner wall surfaces of the through-holes T has been reduced in step (8). Accordingly, when the inner wall surfaces of the through-holes T are coated with an electrically conductive material in this step, intrusion of the electrically conductive material into the space can be reduced and thus electrical short circuit between adjacent through-hole conductors 8 can be reduced.

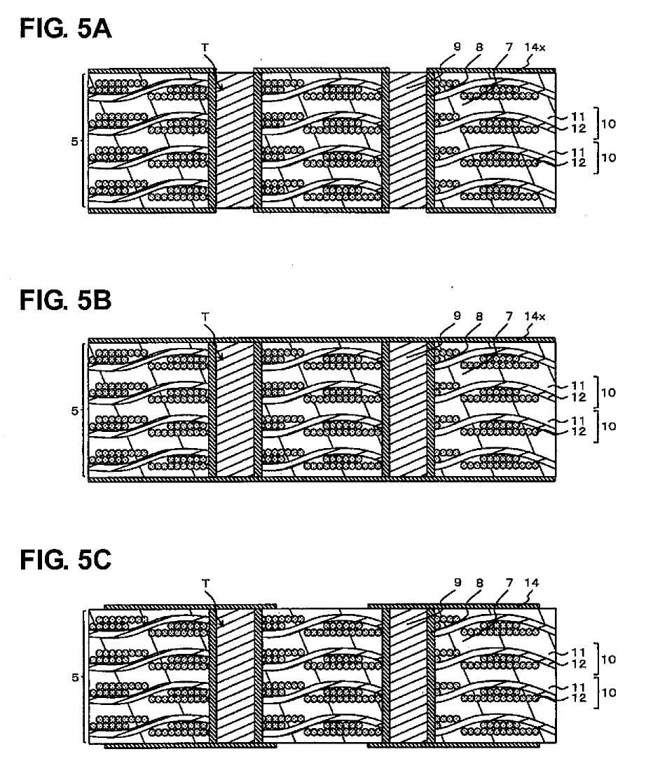

(10) As shown in FIG. 5A, the inside of each of the cylindrical through-hole conductors 11 is filled with a resin material or the like to form insulators 9.

(11) As shown in FIG. 5B, exposed portions of the insulators 9 are coated with an electrically conducive material. The coating with such an electrically conductive material is performed by, for example, an electroless plating method, an evaporation method, a CVD method, a sputtering method, or the like.

(12) As shown in FIG. 5C, copper foils 14x are patterned to form conductive layers 14. The copper foils 14x are patterned by a known photolithography technology, etching, and the like.

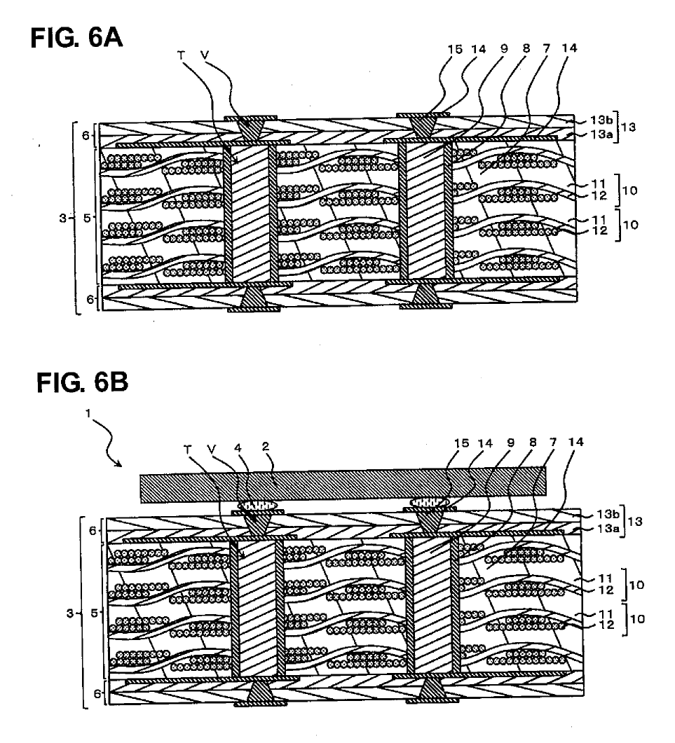

(13) As shown in FIG. 6A, circuit portions 6 are formed on both surfaces of the resin substrate 5. Specifically, the circuit portions 6 can be formed, for example, as follows.

First, a second insulating layer 13b is bonded to each of the conductive layers 14, with a first insulating layer 13a therebetween, to form insulating layers 13 on both surfaces of the resin substrate 5. The bonding is performed by heating under pressure using, for example, a hot-press machine.

Next, via-holes V are formed in each of the insulating layers 13 to expose at least a portion of the corresponding conductive layer 14 in the via-holes V. The via-holes V are formed using, for example, a YAG laser device or a carbon dioxide laser device. Note that the via-holes V can be formed so that the opening width thereof is tapered toward the resin substrate 5 by adjusting the output of a laser beam.

Next, a via-conductor 13 is formed in each of the via-holes V, and an conductive layer 14 is formed on the upper surface of each of the insulating layers 13, thus forming the circuit portions 6. The via-conductors 13 and the conductive layers 14 are formed by a known semi-additive process, subtractive process, full-additive process, or the like. In particular, they are preferably formed by the semi-additive process.

By forming the circuit portions 6 on both surfaces of the resin substrate 5 as described above, the circuit substrate 3 can be prepared. Note that a multilayer circuit substrate 3 can also be prepared by repeating this step.

(14) As shown in FIG. 6B, an electronic component 2 is flip-chip mounted on the circuit substrate 3 through bumps 4, thus preparing the mounting structure 1.

As described above, in the method for manufacturing the mounting structure 1 according to this embodiment, in steps (3) and (4), the first pressure is applied to the laminate 7x in which the incompletely polymerized resin is softened by heating to a temperature lower than the polymerization initiation temperature thereof, and in step (5), the laminate 7x is heated to the polymerization initiation temperature of the incompletely polymerized resin or higher while applying the second pressure lower than the first pressure.

That is, the method for manufacturing the mounting structure 1 according to this embodiment includes a step of heating the resin sheets 10x from a first temperature range which is lower than the polymerization initiation temperature of the incompletely polymerized resin to a second temperature range which is higher than the polymerization initiation temperature of the incompletely polymerized resin and reducing a pressure applied to the resin sheets 10x, wherein when the pressure applied to the resin sheets 10x in the first temperature range is defined as a first pressure and the pressure applied to the resin sheets 10x in the second temperature range is defined as a second pressure, the second pressure is set to be lower than the first pressure.

According to the method for manufacturing the mounting structure 1 of this embodiment, in step (4), since the first pressure is applied to the laminate 7x in which the incompletely polymerized resin is softened to discharge air bubbles between fibers of the base material 12 outside the laminate 7x, air bubbles remaining in the resin substrate 5 can be decreased.

In addition, in steps (5) and (7), since the laminate 7x is heated to the polymerization initiation temperature of the incompletely polymerized resin or higher to polymerize molecules of the resin, the viscosity of the incompletely polymerized resin portion 11x is increased by the polymerization reaction. However, since step (4) is conducted before steps (5) and (7), air bubbles can be efficiently discharged outside the laminate 7x in step (4).

The present invention is not limited to the embodiment described above, and various changes, improvements, and the like can be made within a scope that does not deviate from the gist of the present invention.

For example, the above embodiment of the present invention has been described using, as an example, a production method in which a plurality of resin sheets are stacked in step (2) to form a laminate. Alternatively, only a single resin sheet may be used without forming a laminate. Alternatively, after step (4) or (5), a plurality of resin sheets may be stacked to form a laminate.

The above embodiment of the present invention has been described using, as an example, a production method in which step (4) is conducted after step (3). Alternatively, step (3) and step (4) may be conducted at the same time.

The above embodiment of the present invention has been described using, as an example, a production method in which, in step (5), a laminate is heated to the polymerization initiation temperature of an incompletely polymerized resin or higher while applying a second pressure lower than a first pressure. However, it is sufficient that step (5) includes a step of reducing the pressure applied to resin sheets from the first pressure to the second pressure lower than the first pressure and a step of heating the resin sheets to the polymerization initiation temperature of the incompletely polymerized resin or higher. For example, after the step of reducing the pressure applied to the resin sheets from the first pressure to the second pressure is conducted, the step of heating the resin sheets to the polymerization initiation temperature of the incompletely polymerized resin or higher may then be conducted.

The above embodiment of the present invention has been described using, as an example, a production method in which, in steps (6) and (7), a resin substrate including an insulating base and copper foils is prepared. Alternatively, in (6) and (7), a resin substrate 5 that does not include copper foils 14x may be prepared.

The above embodiment of the present invention has been described using, as an example, a configuration in which a woven fabric in which fibers are woven in the lengthwise and widthwise directions is used as the base material. Alternatively, a material in which fibers are arranged in one direction may also be used as the base material.

The above embodiment of the present invention has been described using, as an example, a configuration in which the number of insulating layers formed on each of the upper surface and the lower surface of a resin substrate is one. Alternatively, the number of insulating layers may be plural.

In above embodiment of the present invention, the description has been made of a configuration in which an electronic component is flip-chip mounted on the upper surface of a circuit substrate. Alternatively, an electronic component may be mounted on the upper surface of a circuit substrate by wire bonding.

What is claimed is:

1. A method for manufacturing a resin substrate comprising:
heating a resin sheet including fibers and a resin containing incompletely polymerized molecules to a temperature lower than a polymerization initiation temperature of the resin in order to soften the resin;
applying a first pressure to the resin sheet to discharge air bubbles between the fibers outside the resin sheet;
decreasing the pressure applied to the resin sheet from the first pressure to a second pressure lower than the first pressure; and
heating the resin sheet to the polymerization initiation temperature of the resin or higher to polymerize the molecules of the resin and to discharge a gas generated by the polymerization outside the resin sheet.

2. The method for manufacturing the resin substrate according to claim 1,
wherein heating the resin sheet to the temperature lower than the polymerization initiation temperature of the resin, and
applying the first pressure to the resin sheet are conducted at the same time.

3. The method for manufacturing the resin substrate according to claim 1,
wherein decreasing the pressure applied to the resin sheet from the first pressure to the second pressure, and
heating the resin sheet to the polymerization initiation temperature of the resin or higher
are conducted at the same time.

4. The method for manufacturing the resin substrate according to claim 1,
wherein decreasing the pressure applied to the resin sheet from the first pressure to the second pressure includes
detaching a pressing member that is in contact with the resin sheet from the resin sheet.

5. The method for manufacturing the resin substrate according to claim 1, further comprising:
after heating the resin sheet to the polymerization initiation temperature of the resin or higher,
placing a metal foil on each of the upper surface and the lower surface of the resin sheet; and
heating the resin sheet to the polymerization initiation temperature of the resin or higher while applying a third pressure higher than the second pressure to the resin sheet.

6. A method for manufacturing a circuit substrate comprising:
forming an conductive layer on the resin substrate according to claim 1.

7. A method for manufacturing a mounting structure comprising: mounting an electronic component on the circuit substrate according to claim 6 and electrically connecting the electronic component to the conductive layer.

8. A method for manufacturing a resin substrate comprising:
heating a resin sheet including fibers and a resin containing incompletely polymerized molecules from a first temperature range which is lower than a polymerization initiation temperature of the resin to a second temperature range which is higher than the polymerization initiation temperature of the resin and reducing a pressure applied to the resin sheet,
wherein when the pressure applied to the resin sheet in the first temperature range is defined as a first pressure and the pressure applied to the resin sheet in the second temperature range is defined as a second pressure, the second pressure is lower than the first pressure.

9. A circuit substrate comprising:
a resin substrate including a resin and fibers covered with the resin,
wherein, in a cross section cut in the thickness direction of the resin substrate, the diameter of air bubbles contained between the fibers is 3 μm or less.

10. The circuit substrate according to claim 9,
wherein, in a cross section cut in the thickness direction of the resin substrate, the diameter of air bubbles contained between the fibers is 0.1 μm or more.
